(19) United States
(12) Patent Application Publication
(10) Pub. No.: US 2024/0219832 A1
(43) Pub. Date: Jul. 4, 2024

(54) PHOTOSENSITIVE COMPOSITION

(71) Applicant: JSR CORPORATION, Tokyo (JP)

(72) Inventors: Tomoyuki MATSUMOTO, Minato-ku, Tokyo (JP); Ryuu MATSUMOTO, Minato-ku, Tokyo (JP); Atsushi ITO, Minato-ku, Tokyo (JP)

(73) Assignee: JSR CORPORATION, Tokyo (JP)

(21) Appl. No.: 18/554,029

(22) PCT Filed: Apr. 6, 2022
(86) PCT No.: PCT/JP2022/017183

§ 371 Date: Oct. 5, 2023

(30) Foreign Application Priority Data
Apr. 23, 2021 (JP) 2021-073406

(51) Int. Cl. G03F 7/038; G03F 7/033

(52) U.S. Cl. CPC G03F 7/038; G03F 7/033

(57) ABSTRACT

An object of the present invention is to provide a photosensitive composition capable of producing a pattern having a precise shape without causing curing defects of a coating film even when the time is required from exposure of the coating film to the next step. A photosensitive composition of the present invention contains a polymer (A), a polymerizable compound (B), a photoacid generator (C), and a solvent (D), in which the polymerizable compound (B) includes an epoxy compound (B-1) containing two or more groups represented by the following Formula (1) and a specific epoxy compound (B-2) other than the epoxy compound (B-1), and an epoxy compound containing an epoxy group fused to an alicyclic group is contained in an amount of 50 mass % or more with respect to a total of 100 mass % of the polymerizable compound (B).

$$- L - Ep \qquad ( 1 )$$

### TECHNICAL FIELD

The present invention relates to a photosensitive composition, a method for forming a pattern using the photosensitive composition, and a method for producing a plated shaped article.

### BACKGROUND ART

In recent years, there has been an increasing demand for high-density mounting of a connection terminal such as a bump of a semiconductor element or a display element such as a liquid crystal display or a touch panel, and thus precision has been progressing.

In general, a bump and others are plated shaped articles, and are produced by forming a resist pattern on a substrate having a metal foil such as copper using a photosensitive composition and performing plating using the resist pattern as a mask, as described in Patent Literature 1.

For this reason, in accordance with the precision of, for example, a bump, it is also required for a resist pattern for use in the production of the bump to be precise.

### CITATION LIST

### Patent Literature

Patent Literature 1: JP 2006-285035 A

### SUMMARY OF INVENTION

### Technical Problem

When a pattern such as a resist pattern is produced using a photosensitive composition, usually, the photosensitive composition is applied onto a substrate to form a coating film, the coating film is exposed, and then a heat treatment is performed as necessary to develop the coating film. In an actual production step, there is a case where a predetermined time is given after the exposure of the coating film and before the next step such as a heat treatment, that is, a so-called delay is performed. In a case where the coating film is delayed after exposure, curing defects of the coating film occur, and the shape of the pattern may be deteriorated. That is, when the time from the exposure of the coating film to the next step such as a heat treatment (post exposure delay: PED) becomes long, the shape of the pattern may be deteriorated.

An object of the present invention is to provide a photosensitive composition capable of producing a pattern having a precise shape without causing curing defects of a coating film even when the time is required from exposure of the coating film to the next step.

### Solution to Problem

The present invention that achieves the above object relates to, for example, the following [1] to [10].

[1] A photosensitive composition containing a polymer (A), a polymerizable compound (B), a photoacid generator (C), and a solvent (D),

in which the polymerizable compound (B) includes an epoxy compound (B-1) and an epoxy compound (B-2) shown below, and an epoxy compound containing an epoxy group fused to an alicyclic group is contained in an amount of 50 mass % or more with respect to a total of 100 mass % of the polymerizable compound (B).

Epoxy compound (B-1): an epoxy compound containing two or more groups represented by the following Formula (1) and one or more epoxy groups fused to an alicyclic group.

$$- L - Ep \qquad ( 1 )$$

(In Formula (1), L represents a single bond, an alkylene group having 1 to 10 carbon atoms, a carbonyl group, an oxygen atom, or a divalent linking group obtained by a combination thereof, and Ep represents an epoxy group or a group having an epoxy group.)

Epoxy compound (B-2): at least one epoxy compound selected from an epoxy compound containing an epoxy group, in which a moiety excluding the epoxy group is a hydrocarbon group, and an epoxy group-containing silane compound other than the epoxy compound (B-1).

[2] The photosensitive composition according to [1], in which the epoxy compound (B-1) is an epoxy compound represented by the following Formula (1-1).

$$R - {( L - Ep )}_{n} \qquad ( 1 - 1 )$$

(In Formula (1-1), R represents an n-valent organic group, n represents an integer of 2 to 6, and L and Ep are as defined in Formula (1).)

[3] The photosensitive composition according to [1] or [2], in which the epoxy group fused to an alicyclic group contained in the epoxy compound (B-1) is a group represented by the following Formula (Ep-1).

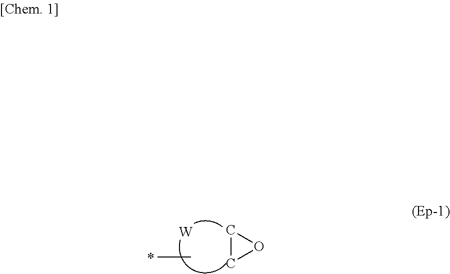

(In Formula (Ep-1), —W— represents a hydrocarbon group that forms an alicyclic hydrocarbon group having 5 to 10 carbon atoms together with C—C, and * represents that the alicyclic hydrocarbon group loses one hydrogen atom and is bonded to the remainder of the epoxy compound (B-1).)

[4] The photosensitive composition according to any one of [1] to [3], in which the epoxy compound (B-2) is at least one epoxy compound selected from a compound represented by the following Formula (Ep-2) and a compound represented by the following Formula (Ep-3).

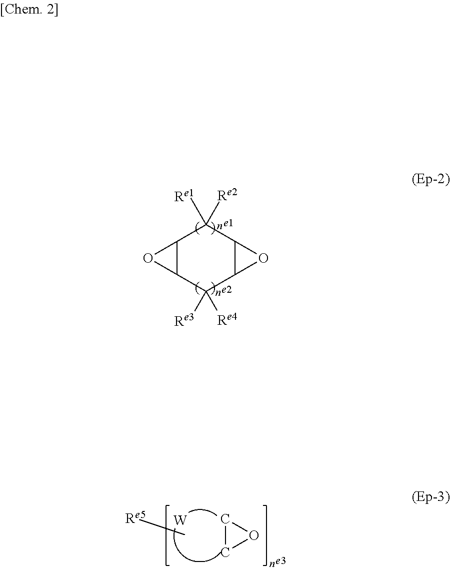

(In Formula (Ep-2), R^{e1} to R^{e4} each independently represent a hydrogen atom or a hydrocarbon group having 1 to 10 carbon atoms, one selected from R^{e1} and R^{e2} and one selected from R^{e3} and R^{e4} may form a single bond or a group represented by a bridge structure of a divalent hydrocarbon group having 1 or 2 carbon atoms, and n^{e1} and n^{e2} represent an integer of 2 to 10, and

in Formula (Ep-3), —W— represents a hydrocarbon group that forms an alicyclic hydrocarbon group having 5 to 10 carbon atoms together with C—C, R^{e5} represents an organic group containing a silicon atom, and n^{e3} represents 1 or 2.)

[5] The photosensitive composition according to any one of [1] to [4], in which the polymer (A) has a structural unit having a phenolic hydroxyl group.

[6] The photosensitive composition according to any one of [1] to [5], in which a ClogP value of the polymer (A) is 1.6 to 3.3.

[7] The photosensitive composition according to any one of [1] to [6], in which a total content of the epoxy compound (B-1) and the epoxy compound (B-2) is 30 to 90 parts by mass with respect to 100 parts by mass of the polymer (A).

[8] The photosensitive composition according to any one of [1] to [7], in which a mass ratio ((B-1):(B-2)) of a content of the epoxy compound (B-1) to a content of the epoxy compound (B-2) is 1:0.05 to 1:1.

[9] A method for forming a pattern, the method including: a step (1) of applying the photosensitive composition according to any one of [1] to [8] onto a substrate to form a coating film; a step (2) of exposing the coating film; and a step (3) of developing the coating film after the exposure.

A method for producing a plated shaped article, the method including a step of performing a plating treatment using the pattern formed by the method for forming a pattern according to [9] as a mask.

### Advantageous Effects of Invention

The photosensitive composition of the present invention can produce a pattern having a precise shape without causing curing defects of a coating film even when the time is required from exposure of the coating film to the next step.

### DESCRIPTION OF EMBODIMENTS

Hereinafter, the present invention will be specifically described.

### [Photosensitive Composition]

A photosensitive composition of the present invention contains the following polymer (A), polymerizable compound (B), photoacid generator (C), and solvent (D).

Note that, in the present invention, a property that does not deteriorate a shape of a pattern even when post exposure delay (PED) (the time from exposure of a coating film to the next step such as a heat treatment) becomes long refers to PED resistance.

### (Polymer (A))

The polymer (A) is a component that forms a main body of a resist formed of the photosensitive composition of the present invention. As the polymer (A), an alkali-soluble resin (A) is preferable. The alkali-soluble resin (A) is a resin having a property that is dissolved in an alkaline developer to such a degree that an intended development treatment can be performed. When the photosensitive composition of the present invention contains the alkali-soluble resin (A), resistance to a plating solution can be imparted to a resist, and development can be performed with an alkaline developer.

Examples of the alkali-soluble resin (A) include alkali-soluble resins described in JP 2008-276194 A, JP 2003-241372 A, JP 2009-531730 A, WO 2010/001691 A, JP 2011-123225 A, JP 2009-222923 A, and JP 2006-243161 A.

A ClogP value of the polymer (A) is preferably 1.6 to 3.3, more preferably 1.8 to 3.1, and still more preferably 2.0 to 2.9. When the ClogP value of the polymer (A) is 1.6 to 3.3, the PED resistance is further improved. logP is an octanol/water partition coefficient, and a greater logP indicates higher lipid solubility. ClogP is a calculated value by ChemDraw.

A weight average molecular weight (Mw) of the alkali-soluble resin (A) measured in terms of polystyrene by gel permeation chromatography is usually 1,000 to 1,000,000, preferably 3,000 to 75,000, and more preferably 5,000 to 50,000.

The alkali-soluble resin (A) preferably contains a phenolic hydroxyl group in terms of improving resistance of a resist to a plating solution.

As the alkali-soluble resin (A) containing a phenolic hydroxyl group, an alkali-soluble resin (A1) having a structural unit represented by the following Formula (2) is preferable.

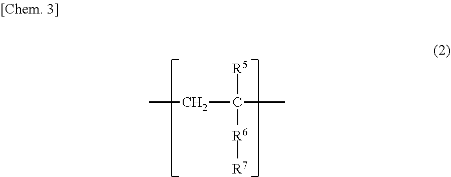

(In Formula (2), R⁵ represents a hydrogen atom, a substituted or unsubstituted alkyl group having 1 to 10 carbon atoms, or a halogen atom, R⁶ represents a single bond or an ester bond, and R⁷ represents a hydroxyaryl group.)

By using the alkali-soluble resin (A1) as the polymer (A), it is possible to obtain a pattern that is difficult to swell in a step (4) of performing a plating treatment on a substrate, which will be described below. As a result, since lifting or peeling of the pattern from the substrate does not occur, it is possible to prevent the plating solution from seeping into an interface between the substrate and the pattern even in a case where the plating is performed for a long time. In addition, resolution of the photosensitive composition can be improved by using the alkali-soluble resin (A1) as the polymer (A).

The polymers (A) may be used alone or in combination of two or more thereof.

### (Polymerizable Compound (B))

When the photosensitive composition of a negative-type of the present invention is applied onto a substrate to form a coating film and the coating film is exposed, the polymerizable compound (B) is polymerized at a cationically polymerizable epoxy group to form a crosslinked body by an action of an acid generated from the photoacid generator (C) in the exposed site.

The polymerizable compound (B) includes an epoxy compound (B-1) and an epoxy compound (B-2) shown below. The polymerizable compound (B) may include a polymerizable compound other than the epoxy compound (B-1) and the epoxy compound (B-2).

In a conventional photosensitive composition, there is a composition containing a compound corresponding to the epoxy compound (B-1) as a polymerizable compound, but there is no composition using the epoxy compound (B-1) and the epoxy compound (B-2) in combination. When the polymerizable compound (B) contains the epoxy compound (B-1) and the epoxy compound (B-2), the photosensitive composition of the present 10 invention exhibits the effect of improving the PED resistance.

Epoxy compound (B-1): an epoxy compound containing two or more groups represented by the following Formula (1) and one or more epoxy groups fused to an alicyclic group.

$$- L - Ep \qquad ( 1 )$$

(In Formula (1), L represents a single bond, an alkylene group having 1 to 10 carbon atoms, a carbonyl group, an oxygen atom, or a divalent linking group obtained by a combination thereof, and Ep represents an epoxy group or a group having an epoxy group.)

Epoxy compound (B-2): at least one epoxy compound selected from an epoxy compound containing an epoxy group, in which a moiety excluding the epoxy group is a hydrocarbon group, and an epoxy group-containing silane compound other than the epoxy compound (B-1).

The epoxy compound (B-1) is preferably an epoxy compound represented by the following Formula (1-1).

$$R - {( L - Ep )}_{n} \qquad ( 1 - 1 )$$

(In Formula (1-1), R represents an n-valent organic group, n represents an integer of 2 to 6, and L and Ep are as defined in Formula (1).)

In addition, the epoxy group fused to an alicyclic group contained in the epoxy compound (B-1) is preferably a group represented by the following Formula (Ep-1).

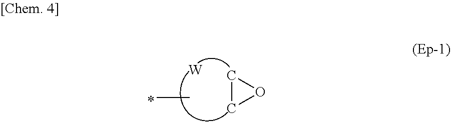

(In Formula (Ep-1), —W— represents a hydrocarbon group that forms an alicyclic hydrocarbon group having 5 to 10 carbon atoms together with C—C, and * represents that the alicyclic hydrocarbon group loses one hydrogen atom and is bonded to the remainder of the epoxy compound (B-1).)

Examples of the alicyclic hydrocarbon group include groups having the following structures.

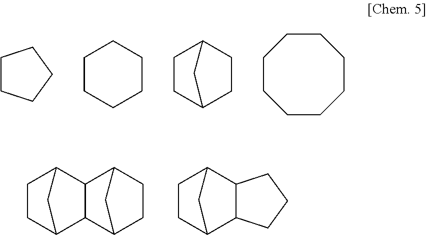

Examples of the epoxy compound (B-1) include a compound represented by the following Formula (B-1-1) and a compound represented by the following Formula (B-1-2).

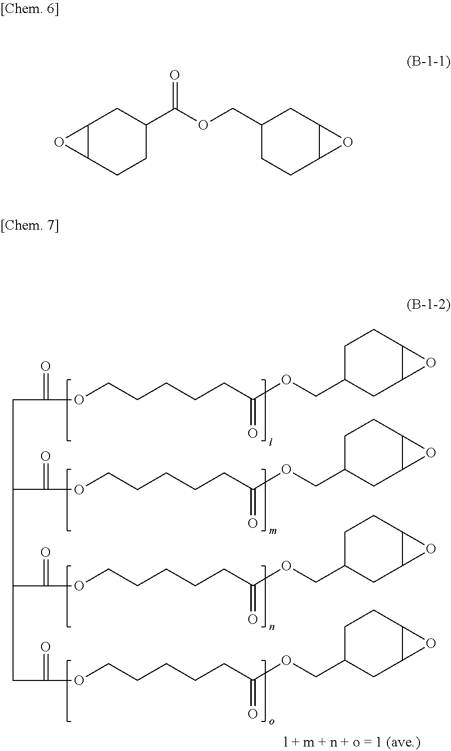

The epoxy compound (B-2) is preferably at least one epoxy compound selected from a compound represented by the following Formula (Ep-2) and a compound represented by the following Formula (Ep-3).

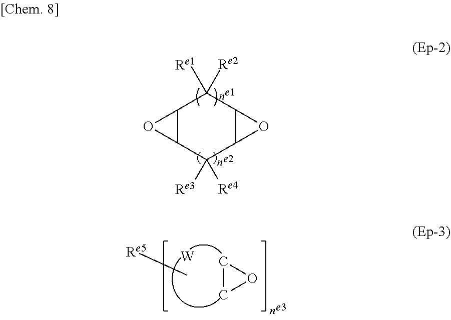

(In Formula (Ep-2), R^{e1} to R^{e4} each independently represent a hydrogen atom or a hydrocarbon group having 1 to 10 carbon atoms, or one selected from R^{e1} and R^{e2} and one selected from R^{e3} and Red form a single bond or a group represented by a bridge structure of a divalent hydrocarbon group having 1 or 2 carbon atoms, R^{e1} to R^{e4} that do not form the single bond or the group represented by a bridge structure each independently represent a hydrogen atom or a hydrocarbon group having 1 to 10 carbon atoms, and n^{e1} and n^{e2} represent an integer of 2 to 10, and

in Formula (Ep-3), —W— represents a hydrocarbon group that forms an alicyclic hydrocarbon group having 5 to 10 carbon atoms together with C—C, R^{e5} represents an organic group containing a silicon atom, and n^{e3} represents 1 or 2.)

Examples of the epoxy compound (B-2) include a compound represented by the following Formula (B-2-1), a compound represented by the following Formula (B-2-2), and a compound represented by the following Formula (B-2-3).

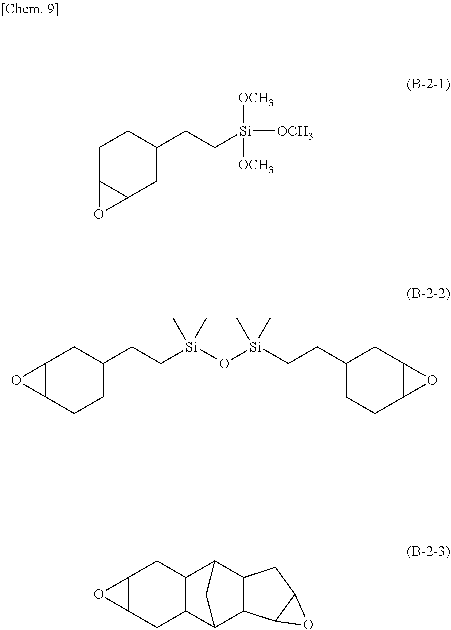 [SMILES: CO[Si](CCC1CCC2OC2C1)(OC)OC ; C[Si](C)(CCC1CCC2OC2C1)O[Si](C)(C)CCC1CCC2OC2C1 ; C1C2OC2CC2C1C1CC2C2C1CC1OC12]

The epoxy compounds (B-1) and (B-2) may be used alone or in combination of two or more thereof.

In addition, the polymerizable compound (B) may include another epoxy compound in a range in which the effect of the present invention is not impaired.

Examples of such another epoxy compound include a compound of the following Formula (b-1) and a compound of the following Formula (b-2).

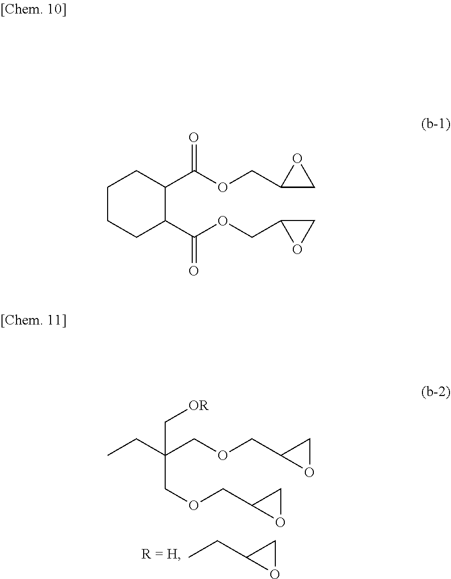

The epoxy compound containing an epoxy group fused to an alicyclic group is contained in the photosensitive composition of the present invention in an amount of 50 mass % or more with respect to a total of 100 mass % of the polymerizable compound (B). Since the epoxy compound contained in an amount of 50 mass % or more with respect to a total of 100 mass % of the polymerizable compound (B) is an epoxy compound containing an epoxy group fused to an alicyclic group, the PED resistance is improved. The amount of the epoxy compound containing an epoxy group fused to an alicyclic group is preferably 60% or more and more preferably 70% or more.

The epoxy group fused to an alicyclic group represents a group in which a monocyclic or polycyclic aliphatic hydrocarbon group and an oxiranyl group share a carbon-carbon bond to form a fused ring structure. The expression “an epoxy compound containing an epoxy group fused to an alicyclic group is contained in an amount of 50 mass % or more with respect to a total of 100 mass % of the polymerizable compound (B)” means that a ratio of a content of an epoxy compound containing an epoxy group fused to an alicyclic group to a total content of an epoxy compound containing an epoxy group fused to an alicyclic group and an epoxy compound not containing an epoxy group fused to an alicyclic group is 50% or more.

A mass ratio ((B-1):(B-2)) of a content of the epoxy compound (B-1) to a content of the epoxy compound (B-2) is preferably 1:0.05 to 1:1, more preferably 1:0.1 to 1:0.75, and still more preferably 1:0.15 to 1:0.50. When the mass ratio is within the above range, the PED resistance is further improved.

In the photosensitive composition of the present invention, the total content of the epoxy compound (B-1) and the epoxy compound (B-2) is preferably 30 to 90 parts by mass, more preferably 35 to 85 parts by mass, and still more preferably 40 to 80 parts by mass, with respect to 100 parts by mass of the polymer (A). When the total content of the epoxy compound (B-1) and the epoxy compound (B-2) is within the above range, the PED resistance is further improved.

Examples of the polymerizable compound other than the epoxy compound (B-1) and the epoxy compound (B-2) include a crosslinking agent having at least two methylol groups and alkoxymethyl groups, a crosslinking agent having at least two oxetane rings, a crosslinking agent having at least two oxazoline rings, a crosslinking agent having at least two isocyanate groups (including a blocked crosslinking agent), and a crosslinking agent having at least two maleimide groups.

In the photosensitive composition of the present invention, the total content of the polymerizable compound (B) is preferably 30 to 90 parts by mass, more preferably 35 to 85 parts by mass, and still more preferably 40 to 80 parts by mass, with respect to 100 parts by mass of the polymer (A).

### (Photoacid Generator (C))

The photoacid generator (C) is a compound that generates an acid by exposure. By the action of this acid, the epoxy group in the polymerizable compound (B) reacts to form a crosslinked body. As a result, the exposed portion of the coating film formed of the present composition becomes insoluble in an alkaline developer, and a negative pattern film can be formed. Thus, the present composition functions as a chemically amplified negative photosensitive composition.

Examples of the photoacid generator (C) include compounds described in JP 2004-317907 A, JP 2014-157252 A, JP 2002-268223 A, JP 2017-102260 A, JP 2016-018075 A, and JP 2016-210761 A. These photoacid generators are described in the present specification.

Specific examples of the photoacid generator (C) include:
onium salt compounds such as diphenyliodonium trifluoromethanesulfonate, diphenyliodonium p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenylsulfonium hexafluoroantimonate, triphenylsulfonium hexafluorophosphate, 4-t-butylphenyl·diphenylsulfonium trifluoromethanesulfonate, 4-t-butylphenyl·diphenylsulfonium benzenesulfonate, 4,7-di-n-butoxynaphthyltetrahydrothiophenium trifluoromethanesulfonate, 4,7-di-n-butoxynaphthyltetrahydrothiophenium·bis(trifluoromethanesulfo nyl)imide anion, 4,7-di-n-butoxynaphthyltetrahydrothiophenium·bis(nonafluorobutylsulfon yl)imide anion, and 4,7-di-n-butoxynaphthyltetrahydrothiophenium·tris(nonafluorobutylsulfo nyl)methide;
halogen-containing compounds such as 1,10-dibromo-n-decane, 1,1-bis(4-chlorophenyl)-2, 2,2-trichoroethane, phenyl-bis(trichloromethyl)-s-triazine, 4-methoxyphenyl-bis(tricholoromethyl)-s-triazine, styryl-bis(trichloromethyl)-s-triazine, and naphthyl-bis(trichloromethyl)-s-triazine;
sulfone compounds such as 4-trisphenacyl sulfone, mesityl phenacyl sulfone, and bis(phenylsulfonyl)methane;
sulfonic acid compounds such as benzoin tosylate, pyrogallol tristrifluoromethanesulfonate, o-nitrobenzyl trifluoromethanesulfonate, and o-nitrobenzyl-p-toluenesulfonate;
sulfonimide compounds such as N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)-4-butyl-naphthylimide, N-(trifluoromethylsulfonyloxy)-4-propylthio-naphthylimide, N-(4-methylphenylsulfonyloxy) succinimide, N-(4-methylphenylsulfonyloxy)phthalimide, N-(4-methylphenylsulfonyloxy)diphenylmaleimide, N-(4-methylphenylsulfonyloxy)bicyclo[2.2.1]hept-5-ene-2,3-dicarboximide, N-(4-fluorophenylsulfonyloxy)bicyclo[2.1.1]heptan-5,6-oxy-2,3-dicarboximide, N-(4-fluorophenylsulfonyloxy) naphthylimide, and N-(10-camphor-sulfonyloxy) naphthylimide; and
diazomethane compounds such as bis(trifluoromethylsulfonyl)diazomethane, bis(cyclohexylsulfonyl)diazomethane, bis(phenylsulfonyl)diazomethane, bis(p-toluenesulfonyl)diazomethane, methylsulfonyl-p-toluenesulfonyldiazomethane, cyclohexylsulfonyl-1,1-dimethylethylsulfonyldiazomethane, and bis(1,1-dimethylethylsulfonyl)diazomethane.

Among them, an onium salt compound and/or a sulfonimide compound are preferable because a patterned film having excellent resolution and plating solution resistance can be formed.

The photosensitive composition of the present invention can contain one or two or more photoacid generators (C).

A content of the photoacid generator (C) in the photosensitive composition of the present invention is usually 0.1 to 20 parts by mass, preferably 0.3 to 15 parts by mass, and more preferably 0.5 to 10 parts by mass, with respect to 100 parts by mass of the polymer (A). When the content of the photoacid generator (C) is within the above range, resolution is further improved.

### (Solvent (D))

By containing the solvent, the photosensitive composition of the present invention can improve handleability of the photosensitive composition, regulate a viscosity, and improve storage stability.

Examples of the solvent include:
alcohols such as methanol, ethanol, and propylene glycol;
cyclic ethers such as tetrahydrofuran and dioxane;
glycols such as ethylene glycol and propylene glycol;
alkylene glycol monoalkyl ethers such as ethylene glycol monomethyl ether, propylene glycol monomethyl ether, and propylene glycol monoethyl ether;
alkylene glycol monoalkyl ether acetates such as ethylene glycol monomethyl ether acetate, propylene glycol monomethyl ether acetate, and propylene glycol monoethyl ether acetate;
aromatic hydrocarbons such as toluene and xylene;
ketones such as acetone, methyl ethyl ketone, methyl isobutyl ketone, cyclohexanone, and 4-hydroxy-4-methyl-2-pentanone;
esters such as ethyl acetate, butyl acetate, ethyl ethoxyacetate, ethyl hydroxyacetate, ethyl 2-hydroxypropionate, ethyl 2-hydroxy-2-methylpropionate, methyl 2-hydroxy-3-methylbutanoate, methyl 3-methoxypropionate, ethyl 3-methoxypropionate, ethyl 3-ethoxypropionate, methyl 3-ethoxypropionate, and ethyl lactate; and
N-methylformamide, N, N-dimethylformamide, N-methylformanilide, N-methylacetamide, N, N-dimethylacetamide, N-methylpyrrolidone, dimethyl sulfoxide, benzyl ethyl ether, dihexyl ether, acetonylacetone, isophorone, caproic acid, caprylic acid, 1-octanol, 1-nonanol, benzyl alcohol, benzyl acetate, ethyl benzoate, diethyl oxalate, γ-butyrolactone, ethylene carbonate, propylene carbonate, and phenyl cellosolve acetate.

The solvents may be used alone or in combination of two or more thereof.

In a case where a resin film having a film thickness of 0.1 to 100 μm is formed, the amount of the solvent may be an amount in which a solid content of the photosensitive composition of the present invention is 5 to 80 mass %. The solid content means a component excluding the solvent among all components contained in the composition.

### (Other Components)

The photosensitive composition of the present invention may contain, as other components, for example, a polymerization initiator, a polymerization inhibitor, a solvent, a surfactant, an adhesion aid, a sensitizer, and an inorganic filler, in a range in which the object and characteristics of the present invention are not impaired.

### [Method for Preparing Photosensitive Composition]

The photosensitive composition of the present invention can be prepared by uniformly mixing the components described above. In order to remove dust, after the components are uniformly mixed, the resulting mixture may be filtered with, for example, a filter.

### [Method for Forming Pattern]

A method for forming a pattern of the present invention includes: a step (1) of applying the photosensitive composition onto a substrate to form a coating film; a step (2) of exposing the coating film; and a step (3) of developing the coating film after the exposure.

In the step (1), the photosensitive composition is applied onto a substrate to form a coating film.

Examples of the substrate include a semiconductor substrate, a glass substrate, a silicon substrate, and a substrate formed by providing a film such as any of various metal films on a surface of a semiconductor plate, a glass plate, or a silicon plate. The shape of the substrate is not particularly limited. The shape may be a flat plate shape or a shape formed by providing recesses (holes) in a flat plate such as a silicon wafer. In the case of a substrate having recesses and including a copper film formed on a surface, the copper film may be provided at the bottom of the recess as in a TSV structure.

As a method for applying the photosensitive composition, for example, a spray method, a roll coating method, a spin coating method, a slit die coating method, a bar coating method, or an inkjet method can be employed, and the spin coating method is particularly preferable. In the case of the spin coating method, a rotation speed is usually 800 to 3,000 rpm and preferably 800 to 2,000 rpm, and a rotation time is usually 1 to 300 seconds and preferably 5 to 200 seconds. After spin coating of the photosensitive composition is performed, the resulting coating film is heated and dried at usually 50 to 180° C., preferably 70 to 160° C., and more preferably 90 to 140° C. for about 1 to 30 minutes.

The film thickness of the coating film is usually 0.1 to 200 μm, preferably 5 to 150 μm, more preferably 20 to 100 μm, and still more preferably 30 to 80 μm.

In the step (2), the coating film is exposed. That is, the coating film is selectively exposed so that a pattern is obtained in the step (3).

The coating film is usually exposed by using, for example, a contact aligner, a stepper, or a scanner via a desired photomask. As the exposure light, light having a wavelength of 200 to 500 nm (example: the i-line (365 nm)) is used. The amount of exposure varies depending on, for example, the types and blending amounts of components in the coating film and the thickness of the coating film, and is usually 1 to 10,000 mJ/cm² in the case of using the i-line as exposure light.

Further, a heat treatment can be performed after exposure. The conditions of the heat treatment after exposure are determined according to, for example, the types and blending amounts of components in the coating film and the thickness of the coating film as appropriate, and are usually 70 to 180° C. and 1 to 60 minutes.

In the step (3), the coating film after the exposure is developed. Thus, a pattern is formed.

As the developer, for example, an aqueous solution of sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5.4.0]-7-undecene, or 1,5-diazabicyclo[4.3.0]-5-nonane can be used. In addition, an aqueous solution obtained by adding an appropriate amount of a water-soluble organic solvent such as methanol or ethanol or a surfactant to the above alkaline aqueous solution can be used as a developer.

A development time varies depending on, for example, the types and blending ratios of components in the composition and the thickness of the coating film, and is usually 30 to 600 seconds. The method of development may be any of, for example, a liquid putting method, a dipping method, a paddle method, a spraying method, and a shower developing method.

The pattern may be washed with, for example, running water. Thereafter, air drying may be performed using, for example, an air gun, or drying is performed under heating such as a hot plate or an oven.

Since the photosensitive composition has high PED resistance as described above, in the method for forming a pattern of the present invention, the shape of the pattern is not deteriorated even when PED, which is the time from the step (2) of exposing the coating film to the heat treatment or the step (3), becomes long.

### [Method for Producing Plated Shaped Article]

A method for producing a plated shaped article of the present invention includes a step of performing a plating treatment on the substrate using the pattern formed by the method for forming a pattern as a mask.

Examples of the plated shaped article include a bump and a wiring line.

The pattern is formed according to the method for forming a pattern described above.

Examples of the plating treatment include wet plating treatments such as an electrolytic plating treatment, an electroless plating treatment, and a hot dipping treatment, and dry plating treatments such as chemical vapor deposition and sputtering.

In the case of forming a wiring line or a connection terminal in processing at a wafer level, the plating treatment is usually performed by an electrolytic plating treatment.

Before an electrolytic plating treatment is performed, the surface of the inner wall of the pattern can be subjected to a pre-treatment such as an ashing treatment, a flux treatment, or a desmear treatment in order to enhance the affinity between the surface of the inner wall of the pattern and the plating solution.

In the case of the electrolytic plating treatment, a layer formed on the inner wall of the pattern by sputtering or an electroless plating treatment can be used as a seed layer, and in the case of using, as the substrate, a substrate having a metal film formed on a surface, the metal film can be used as a seed layer.

A barrier layer may be formed before the seed layer is formed, or the seed layer may be used as a barrier layer.

Examples of the plating solution used for an electrolytic plating treatment include a copper plating solution containing, for example, copper sulfate or copper pyrophosphate; a gold plating solution containing gold potassium cyanide; and a nickel plating solution containing nickel sulfate or nickel carbonate.

For the plating treatment, different plating treatments can be sequentially performed. For example, a solder copper pillar bump can be formed by first performing a copper plating treatment, performing a nickel plating treatment, and then performing a molten solder dipping treatment.

After the step of performing the plating treatment, a step of removing the pattern with a resist stripping liquid may be performed. Removal of the pattern can be performed according to conventional methods.

### EXAMPLES

Hereinafter, the present invention will be described more specifically based on Examples, but the present invention is not limited to these Examples. In the following description of Examples, the term “part (s)” is used to mean “part(s) by mass”.

A weight average molecular weight (Mw) of a polymer is a value calculated in terms of polystyrene in a gel permeation chromatography method under the following conditions.
Column: TSK-M and TSK 2500 columns connected in series, manufactured by Tosoh Corporation
Solvent: tetrahydrofuran
Column temperature: 40° C.
Detection method: refractive index method
Standard substance: polystyrene
GPC apparatus: apparatus name “HLC-8220-GPC”, manufactured by Tosoh Corporation

The components used in Examples and Comparative Examples are shown below.

### (Polymer (A))

A-1: copolymer of p-hydroxystyrene and styrene (p-hydroxystyrene: 80 mol %, styrene: 20 mol %, ClogP: 2.37, Mw: 13,000)

A-2: p-hydroxystyrene polymer (p-hydroxystyrene: 100 mol %, ClogP: 2.20, Mw: 13,000) A-3: copolymer of p-hydroxystyrene and methyl methacrylate (p-hydroxystyrene: 80 mol %, methyl methacrylate: 20 mol %, ClogP: 2.01, Mw: 13,000)

A-4: copolymer of p-hydroxystyrene and n-butyl methacrylate (p-hydroxystyrene: 80 mol %, n-butyl methacrylate: 20 mol %, ClogP: 2.31, Mw: 13,000)

A-5: copolymer of p-hydroxystyrene and hydroxyethyl methacrylate (p-hydroxystyrene: 80 mol %, hydroxyethyl methacrylate: 20 mol %, ClogP: 1.80, Mw: 13,000)

A-6: copolymer of p-hydroxystyrene and hydroxyethyl methacrylate (p-hydroxystyrene: 65 mol %, hydroxyethyl methacrylate: 35 mol %, ClogP: 1.52, Mw: 13,000)

A-7: copolymer of p-hydroxystyrene and 2-ethylhexyl methacrylate (p-hydroxystyrene: 80 mol %, 2-ethylhexyl methacrylate: 20 mol %, ClogP: 2.92, Mw: 13,000)

A-8: copolymer of p-hydroxystyrene and 2-ethylhexyl methacrylate (p-hydroxystyrene: 65 mol %, 2-ethylhexyl methacrylate: 35 mol %, ClogP: 3.37, Mw: 13,000)

### (Polymerizable Compound (B))

B-1-1: compound represented by Formula (B-1-1) (CELLOXIDE 2021P manufactured by Daicel Corporation)

B-1-2: compound represented by Formula (B-1-2) (EPOLIDE GT401, manufactured by Daicel Corporation)

B-2-1: compound represented by Formula (B-2-1) (DOWSIL Z-6043 Silane, manufactured by Dow Inc.)

B-2-2: compound represented by Formula (B-2-2) (X-40-2669, manufactured by Shin-Etsu Silicone Co., Ltd.)

B-2-3: compound represented by Formula (B-2-3) (DE-102, manufactured by ENEOS Corporation)

b-1: compound represented by Formula (b-1)

b-2: compound represented by Formula (b-2) (DENACOL EX-321L, manufactured by Nagase ChemteX Corporation)

### (Photoacid Generator (C))

C-1: compound represented by the following Formula (C-1)

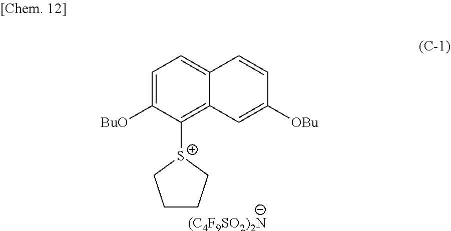

C-2: compound represented by the following Formula (C-2)

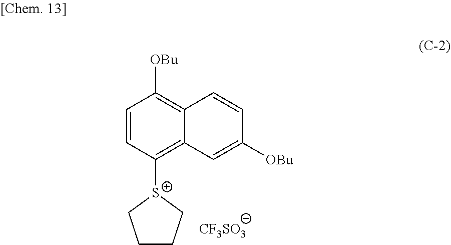

C-3: compound represented by the following Formula (C-3)

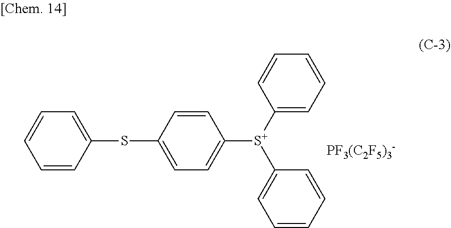 [SMILES: c1ccc(Sc2ccc([S+](c3ccccc3)c3ccccc3)cc2)cc1]

### (Solvent (D))

D-1: 2-methoxy-1-methylethyl acetate (PGMEA)

### (Other Components)

E-1: compound represented by the following Formula (E-1)

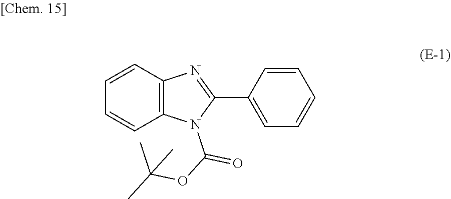 [SMILES: CC(C)(C)OC(=O)n1c(-c2ccccc2)nc2ccccc21]

F-1: diglycerin ethylene oxide (average addition mole number: 18) adduct perfluorononenyl ether (trade name: FTERGENT FTX-218, manufactured by NEOS COMPANY LIMITED)

G: compounds represented by the following Formulas (G-1) to (G-4)

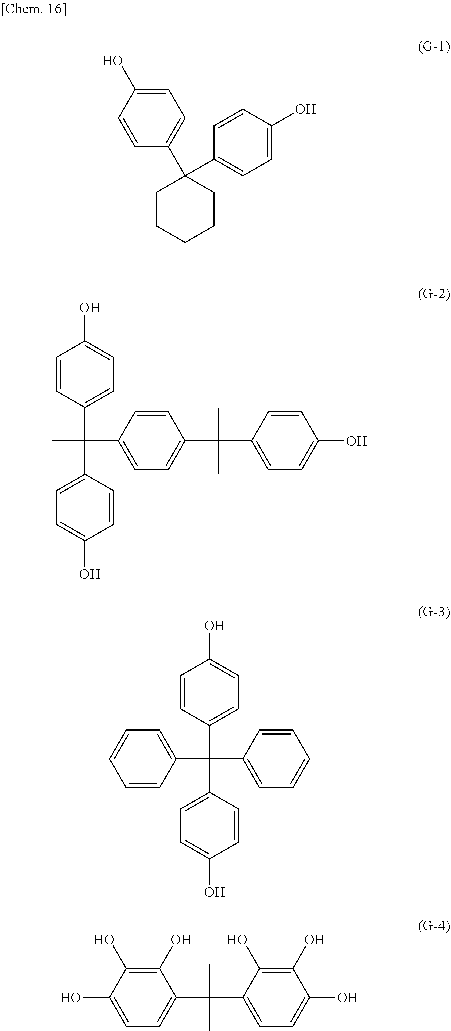 [SMILES: Oc1ccc(C2(c3ccc(O)cc3)CCCCC2)cc1 ; CC(C)(c1ccc(O)cc1)c1ccc(C(C)(c2ccc(O)cc2)c2ccc(O)cc2)cc1 ; Oc1ccc(C(c2ccccc2)(c2ccccc2)c2ccc(O)cc2)cc1 ; CC(C)(c1ccc(O)c(O)c1O)c1ccc(O)c(O)c1O]

H: compounds represented by the following Formulas (H-1) to (H-3)

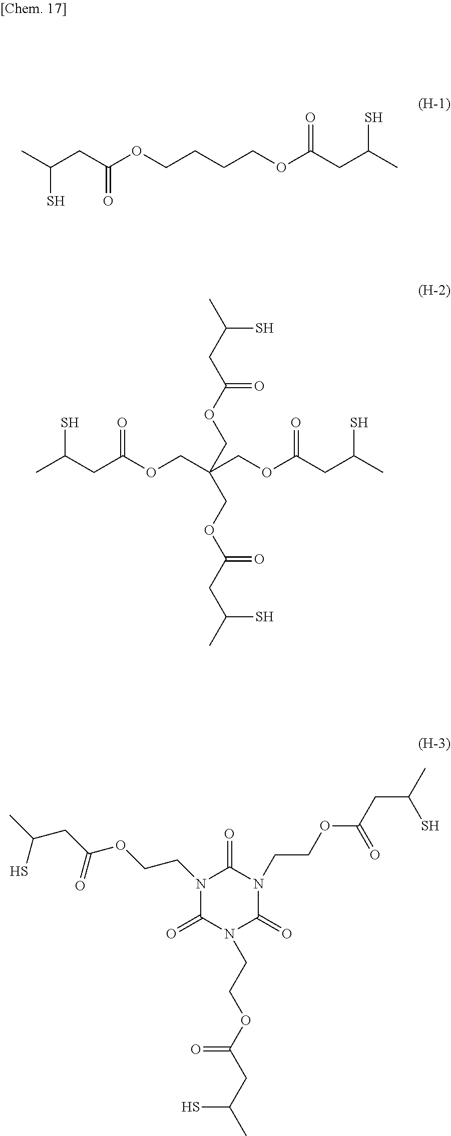

### [Examples 1 to 23 and Comparative Examples 1 to 5]

The respective components were mixed in the amounts shown in Table 1, and the mixture was filtered with a capsule filter (pore diameter: 3 μm), thereby preparing a photosensitive composition. At this time, the total solid concentration (TSC) was adjusted to 55% using the solvent D-1 (2-methoxy-1-methylethyl acetate (PGMEA)).

### (Evaluation of Pattern Shape)

The photosensitive resin composition was applied onto a substrate including a copper sputtered film formed on a 6-inch silicon wafer by a spin coating method, and heating was performed at 120° C. on a hot plate for 300 seconds, thereby forming a coating film having a film thickness of 40 μm. The coating film was exposed via a pattern mask using a stepper (Model “NSR-i12D”, manufactured by Nikon Corporation). The coating film was developed by being immersed in 2.38 mass % tetramethylammonium hydroxide aqueous solution for 200 seconds to form a resist pattern (square pattern) having an opening of 20 μm long×20 μm wide.

The resulting resist pattern was observed with an electron microscope, and the shape of the resist pattern was evaluated according to the following criteria. The results are shown in Table 1.

AA: The pattern is rectangular, there is no roughness on the resist surface, and no resist residue is observed in an unexposed portion.

BB: The pattern is rectangular, and roughness is observed on the resist surface, or a resist residue is observed in an unexposed portion.

CC: The rectangularity of the pattern is impaired, and roughness is observed on the resist surface, or a resist residue is observed in an unexposed portion.

### (Evaluation of PED Resistance)

A coating film was formed in the same manner as described above, exposure was performed, the coating film was delayed for 6 hours (PED: 6 hours), and development was performed in the same manner as described above to attempt to form a resist pattern.

In addition, a coating film was formed in the same manner as described above, exposure was performed, the coating film was delayed for 24 hours (PED: 24 hours), and development was performed in the same manner as described above to attempt to form a resist pattern.

The resulting resist pattern was observed with an electron microscope, and the PED resistance of the photosensitive resin composition was evaluated according to the following criteria. The results are shown in Table 1.

AA: No change is observed in the pattern shape in both cases of PED 6 hours and PED 24 hours.

BB: In the case of PED 24 hours, the pattern shape changes, but in the case of PED 6 hours, the pattern shape does not change.

CC: The pattern shape changes in both cases of PED 6 hours and PED 24 hours.

TABLE 1

| | | | Polymerizable | | Photoacid | | | | | | | | |
|---|---|---|---|---|---|---|---|---|---|---|---|---|---|
| | Polymer (A) | | compound (B) | | generator (C) | | Other components | | | | | | |
| | | Amount | | Amount | | Amount | | Amount | | Amount | Ratio | Pattern | PED |
| | Type | (parts) | Type | (parts) | Type | (parts) | Type | (parts) | Type | (parts) | (%)¹⁾ | shape | resistance |
| Example 1 | A-1 | 100 | B-1-1 | 50 | C-1 | 1.5 | E-1 | 0.07 | G-2 | 10 | 100 | AA | AA |
| | | | B-2-1 | 10 | | | F-1 | 0.1 | H-2 | 1 | | | |
| Example 2 | A-2 | 100 | B-1-1 | 50 | C-1 | 1.5 | E-1 | 0.07 | G-2 | 10 | 100 | AA | AA |
| | | | B-2-1 | 10 | | | F-1 | 0.1 | H-2 | 1 | | | |
| Example 3 | A-3 | 100 | B-1-1 | 50 | C-1 | 1.5 | E-1 | 0.07 | G-2 | 10 | 100 | AA | AA |
| | | | B-2-1 | 10 | | | F-1 | 0.1 | H-2 | 1 | | | |
| Example 4 | A-4 | 100 | B-1-1 | 50 | C-1 | 1.5 | E-1 | 0.07 | G-2 | 10 | 100 | AA | AA |
| | | | B-2-1 | 10 | | | F-1 | 0.1 | H-2 | 1 | | | |
| Example 5 | A-5 | 100 | B-1-1 | 50 | C-1 | 1.5 | E-1 | 0.07 | G-2 | 10 | 100 | AA | AA |
| | | | B-2-1 | 10 | | | F-1 | 0.1 | H-2 | 1 | | | |
| Example 6 | A-6 | 100 | B-1-1 | 50 | C-1 | 1.5 | E-1 | 0.07 | G-2 | 10 | 100 | AA | BB |
| | | | B-2-1 | 10 | | | F-1 | 0.1 | H-2 | 1 | | | |
| Example 7 | A-7 | 100 | B-1-1 | 50 | C-1 | 1.5 | E-1 | 0.07 | G-2 | 10 | 100 | AA | AA |
| | | | B-2-1 | 10 | | | F-1 | 0.1 | H-2 | 1 | | | |
| Example 8 | A-8 | 100 | B-1-1 | 50 | C-1 | 1.5 | E-1 | 0.07 | G-2 | 10 | 100 | BB | AA |
| | | | B-2-1 | 10 | | | F-1 | 0.1 | H-2 | 1 | | | |
| Example 9 | A-1 | 100 | B-1-1 | 50 | C-2 | 1.5 | E-1 | 0.07 | G-2 | 10 | 100 | AA | AA |
| | | | B-2-1 | 10 | | | F-1 | 0.1 | H-2 | 1 | | | |
| Example 10 | A-1 | 100 | B-1-1 | 50 | C-3 | 1.5 | E-1 | 0.01 | G-2 | 10 | 100 | AA | AA |
| | | | B-2-1 | 10 | | | F-1 | 0.1 | H-2 | 1 | | | |
| Example 11 | A-1 | 100 | B-1-2 | 50 | C-1 | 1.5 | E-1 | 0.07 | G-2 | 10 | 100 | AA | AA |
| | | | B-2-1 | 10 | | | F-1 | 0.1 | H-2 | 1 | | | |
| Example 12 | A-1 | 100 | B-1-1 | 50 | C-1 | 1.5 | E-1 | 0.07 | G-2 | 10 | 100 | AA | AA |
| | | | B-2-2 | 10 | | | F-1 | 0.1 | H-2 | 1 | | | |
| Example 13 | A-1 | 100 | B-1-1 | 50 | C-1 | 1.5 | E-1 | 0.07 | G-2 | 10 | 100 | AA | AA |
| | | | B-2-3 | 10 | | | F-1 | 0.1 | H-2 | 1 | | | |
| Example 14 | A-1 | 100 | B-1-1 | 15 | C-1 | 1.5 | E-1 | 0.07 | G-2 | 10 | 100 | BB | BB |
| | | | B-2-1 | 10 | | | F-1 | 0.1 | H-2 | 1 | | | |
| Example 15 | A-1 | 100 | B-1-1 | 85 | C-1 | 1.5 | E-1 | 0.07 | G-2 | 10 | 100 | BB | AA |
| | | | B-2-1 | 10 | | | F-1 | 0.1 | H-2 | 1 | | | |
| Example 16 | A-1 | 100 | B-1-1 | 50 | C-1 | 1.5 | E-1 | 0.07 | G-2 | 10 | 100 | AA | BB |
| | | | B-2-1 | 1 | | | F-1 | 0.1 | H-2 | 1 | | | |
| Example 17 | A-1 | 100 | B-1-1 | 30 | C-1 | 1.5 | E-1 | 0.07 | G-2 | 10 | 100 | BB | AA |
| | | | B-2-1 | 40 | | | F-1 | 0.1 | H-2 | 1 | | | |
| Example 18 | A-1 | 100 | B-1-1 | 40 | C-1 | 1.5 | E-1 | 0.07 | G-2 | 10 | 100 | AA | AA |
| | | | B-2-1 | 10 | | | F-1 | 0.1 | H-2 | 1 | | | |
| | | | b-1 | 10 | | | | | | | | | |
| Example 19 | A-1 | 100 | B-1-1 | 50 | C-1 | 1.5 | E-1 | 0.07 | G-1 | 10 | 100 | AA | AA |
| | | | B-2-1 | 10 | | | F-1 | 0.1 | H-2 | 1 | | | |
| Example 20 | A-1 | 100 | B-1-1 | 50 | C-1 | 1.5 | E-1 | 0.07 | G-3 | 10 | 100 | AA | AA |
| | | | B-2-1 | 10 | | | F-1 | 0.1 | H-2 | 1 | | | |
| Example 21 | A-1 | 100 | B-1-1 | 50 | C-1 | 1.5 | E-1 | 0.07 | G-4 | 10 | 100 | AA | AA |
| | | | B-2-1 | 10 | | | F-1 | 0.1 | H-2 | 1 | | | |
| Example 22 | A-1 | 100 | B-1-1 | 50 | C-1 | 1.5 | E-1 | 0.07 | G-2 | 10 | 100 | AA | AA |
| | | | B-2-1 | 10 | | | F-1 | 0.1 | H-1 | 1 | | | |
| Example 23 | A-1 | 100 | B-1-1 | 50 | C-1 | 1.5 | E-1 | 0.07 | G-2 | 10 | 100 | AA | AA |
| | | | B-2-1 | 10 | | | F-1 | 0.1 | H-3 | 1 | | | |
| Comparative | A-1 | 100 | B-1-1 | 50 | C-1 | 1.5 | E-1 | 0.07 | G-2 | 10 | 100 | AA | CC |
| Example 1 | | | | | | | F-1 | 0.1 | H-2 | 1 | | | |
| Comparative | A-1 | 100 | B-2-1 | 55 | C-1 | 1.5 | E-1 | 0.07 | G-2 | 10 | 100 | CC | AA |
| Example 2 | | | | | | | F-1 | 0.1 | H-2 | 1 | | | |
| Comparative | A-1 | 100 | B-2-1 | 10 | C-1 | 1.5 | E-1 | 0.07 | G-2 | 10 | 100 | CC | CC |
| Example 3 | | | b-1 | 50 | | | F-1 | 0.1 | H-2 | 1 | | | |
| Comparative | A-1 | 100 | B-2-1 | 10 | C-1 | 1.5 | E-1 | 0.07 | G-2 | 10 | 100 | CC | CC |
| Example 4 | | | b-2 | 50 | | | F-1 | 0.1 | H-2 | 1 | | | |
| Comparative | A-1 | 100 | B-1-1 | 10 | C-1 | 1.5 | E-1 | 0.07 | G-2 | 10 | 100 | CC | CC |
| Example 5 | | | B-2-1 | 10 | | | F-1 | 0.1 | H-2 | 1 | | | |
| | | | b-1 | 40 | | | | | | | | | |

¹⁾Ratio of epoxy compound containing epoxy group fused to alicyclic group contained in epoxy compound to total of 100 mass % of epoxy compounds (B-1) and (B-2)

1. A photosensitive composition comprising:
a polymer (A);
a polymerizable compound (B);
a photoacid generator (C); and
a solvent (D),
wherein the polymerizable compound (B) comprises:
an epoxy compound (B-1) which comprises two or more groups represented by Formula (1) and one or more epoxy groups fused to an alicyclic group; and
an epoxy compound (B-2) which is a compound other than the epoxy compound (B-1), and is at least one epoxy compound selected from the group consisting of an epoxy compound comprising an epoxy group, in which a moiety excluding the epoxy group is a hydrocarbon group, and an epoxy group-containing silane compound:
$$\underline{- L - Ep ,} \qquad ( 1 )$$
wherein, in Formula (1), L represents a single bond, an alkylene group having 1 to 10 carbon atoms, a carbonyl group, an oxygen atom, or a divalent linking group obtained by a combination thereof, and Ep represents an epoxy group or a group comprising an epoxy group, and
wherein the polymerizable compound (B) comprises an epoxy compound containing an epoxy group fused to an alicyclic group in an amount of 50 mass % or more with respect to a total of 100 mass % of the polymerizable compound (B).

2. The photosensitive composition according to claim 1, wherein the epoxy compound (B-1) is an epoxy compound represented by Formula (1-1):
$$\underline{R - {( L - Ep )}_{n} ,} \qquad ( 1 - 1 )$$
wherein in Formula (1-1), R represents an n-valent organic group, n represents an integer of 2 to 6, and L and Ep are each as defined in Formula (1).

3. The photosensitive composition according to claim 1, wherein the epoxy group fused to an alicyclic group contained in the epoxy compound (B-1) is a group represented by Formula (Ep-1), 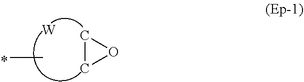
wherein in Formula (Ep-1), —W— represents a hydrocarbon group that forms an alicyclic hydrocarbon group having 5 to 10 carbon atoms together with C—C, and * represents a site bonded to the remainder of the epoxy compound (B-1).

4. The photosensitive composition according to claim 1, wherein the epoxy compound (B-2) is at least one epoxy compound selected from the group consisting of a compound represented by Formula (Ep-2) and a compound represented by Formula (Ep-3), 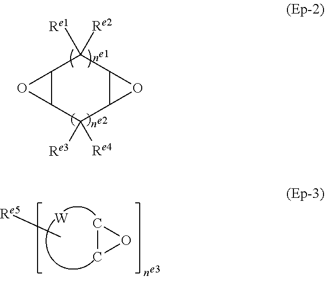
wherein in Formula (Ep-2), R^{e1} to R^{e4} each independently represent a hydrogen atom or a hydrocarbon group having 1 to 10 carbon atoms, optionally, one selected from R^{e1} and R^{e2} and one selected from R^{e3} and R^{e4} forms a single bond or a group represented by a bridge structure of a divalent hydrocarbon group having 1 or 2 carbon atoms, and n^{e1} and n^{e2} each represent an integer of 2 to 10, and
in Formula (Ep-3), —W— represents a hydrocarbon group that forms an alicyclic hydrocarbon group having 5 to 10 carbon atoms together with C—C, R^{e5} represents an organic group containing a silicon atom, and n^{e3} represents 1 or 2.

5. The photosensitive composition according to claim 1, wherein the polymer (A) has a structural unit having a phenolic hydroxyl group.

6. The photosensitive composition according to claim 1, wherein a ClogP value of the polymer (A) is 1.6 to 3.3.

7. The photosensitive composition according to claim 1, wherein a total content of the epoxy compound (B-1) and the epoxy compound (B-2) is 30 to 90 parts by mass with respect to 100 parts by mass of the polymer (A).

8. The photosensitive composition according to claim 1, wherein a mass ratio ((B-1):(B-2)) of a content of the epoxy compound (B-1) to a content of the epoxy compound (B-2) is 1:0.05 to 1:1.

9. A method for forming a pattern, the method comprising:
applying the photosensitive composition according to claim 1 onto a substrate to form a coating film;
exposing the coating film; and
developing the coating film after the exposing of the coating film.

10. A method for producing a plated shaped article, the method comprising performing a plating treatment using the pattern formed by the method for forming a pattern according to claim 9 as a mask.
